(19) United States
(12) Patent Application Publication
(10) Pub. No.: US 2015/0371862 A1
(43) Pub. Date: Dec. 24, 2015

(54) METHOD OF FORMING PATTERN

(71) Applicant: Powerchip Technology Corporation, Hsinchu (TW)

(72) Inventors: Wen-Yi Wong, Kinmen County (TW); Tuz-Wen Weng, Hsinchu City (TW)

(21) Appl. No.: 14/497,330

(22) Filed: Sep. 26, 2014

(30) Foreign Application Priority Data
Jun. 20, 2014 (TW) 103121398

(51) Int. Cl. H01L 21/308

(52) U.S. Cl. CPC H01L 21/3086

(57) ABSTRACT

A method of forming a pattern including following steps is provided. A wafer is provided, wherein the wafer includes a plurality of wafer interior dies and a plurality of wafer edge dies. A first pattern is formed on each of the wafer interior dies, and a second pattern is formed on each of the wafer edge dies. A method of forming the first patterns includes performing at least two exposure processes, and a method of forming the second patterns includes performing at least one of the at least two exposure processes, wherein a number of the exposure processes performed for forming the second patterns is less than a number of the exposure processes performed for forming the first patterns.

### CROSS-REFERENCE TO RELATED APPLICATION

This application claims the priority benefit of Taiwan application serial no. 103121398, filed on Jun. 20, 2014. The entirety of the above-mentioned patent application is hereby incorporated by reference herein and made a part of this specification.

### BACKGROUND OF THE INVENTION

1. Field of the Invention

The invention relates to a method for semiconductor fabrication, and more particularly, relates to a method of forming a pattern.

2. Description of Related Art

With rapid advancement of semiconductor fabricating technology, in order to improve speed and performance of element, a dimension of all circuit elements must be continuously scaled down to continuously increase integrity for the elements. Generally, under the design trend of scaling down the circuit elements, a photolithography process plays an important role in the semiconductor fabrication. In the semiconductor fabrication, the photolithography process is used to define a range and a size of critical dimension (CD) for processes such as patterning each film layer.

Patterns are generally formed on a photoresist layer by using the photolithography process. Thereafter, a dry etching process or a wet etching process is then performed by using the photoresist layer as an etching mask, so that the patterns in the photoresist layer are transferred to a material layer thereunder.

However, the patterns on wafer edge dies located on wafer edges are prone to collapse in the semiconductor fabrication and thereby lower a yield rate of products.

### SUMMARY OF THE INVENTION

The invention provides a method of forming a pattern, which is capable of effectively preventing the situation in which the patterns collapse on the wafer edge dies, so as to increase the yield rate of products.

A method of forming a pattern proposed by the invention includes the following steps. A wafer is provided, wherein the wafer includes a plurality of wafer interior dies and a plurality of wafer edge dies. A first pattern is formed on each of the wafer interior dies, and a second pattern is formed on each of the wafer edge dies. A method of forming the first patterns includes performing at least two exposure processes, and a method of forming the second patterns includes performing at least one of the at least two exposure processes, wherein a number of the exposure processes performed for forming the second patterns is less than a number of the exposure processes performed for forming the first patterns.

According to an embodiment of the invention, in said method of forming the pattern, the at least two exposure processes are performed on different photoresist layers for example.

According to an embodiment of the invention, in said method of forming the pattern, the at least two exposure processes are performed on the same photoresist layer for example.

According to an embodiment of the invention, in said method of forming the pattern, the methods of forming the first patterns and the second patterns further include forming at least one photoresist layer on the wafer.

According to an embodiment of the invention, in said method of forming the pattern, the methods of forming the first patterns and the second patterns further include performing at least one development process on the wafer.

According to an embodiment of the invention, in said method of forming the pattern, the methods of forming the first patterns and the second patterns further include: performing at least one etching process on a material layer by using at least one patterned photoresist layer formed by the at least two exposure processes as a mask.

According to an embodiment of the invention, in said method of forming the pattern, the first patterns and the second patterns are a photoresist pattern for example.

According to an embodiment of the invention, in said method of forming the pattern, the first patterns and the second patterns are a physical pattern or an opening pattern for example.

According to an embodiment of the invention, in said method of forming the pattern, a method of making the number of the exposure processes performed for forming the second patterns less than the number of the exposure processes performed for forming the first patterns includes: shielding the wafer edge dies by using a mask blade when performing the at least one of the at least two exposure processes.

According to an embodiment of the invention, in said method of forming the pattern, a dimension of the second patterns is, for example, greater than a dimension of the first patterns.

Based on above, in the method of forming the pattern proposed by the invention, because the number of the exposure processes performed for forming the second patterns is less than the number of the exposure processes performed for forming the first patterns, a stability of the second patterns on the wafer edge dies may be higher. Therefore, the situation in which the patterns collapse on the wafer edge dies may be effectively prevented to increase the yield rate of products.

To make the above features and advantages of the disclosure more comprehensible, several embodiments accompanied with drawings are described in detail as follows.

### BRIEF DESCRIPTION OF THE DRAWINGS

FIG. 1 is a flowchart illustrating a method of forming a pattern according to an embodiment of the invention.

FIG. 2 is a schematic view illustrating a wafer according to an embodiment of the invention.

FIG. 3A to FIG. 3B are top views illustrating a process flow for the patterns according to an embodiment of the invention.

FIG. 4A to FIG. 4D are top views illustrating a process flow for the patterns according to another embodiment of the invention.

FIG. 5A to FIG. 5D are cross-sectional views illustrating a process flow for the patterns according to another embodiment of the invention.

### DESCRIPTION OF THE EMBODIMENTS

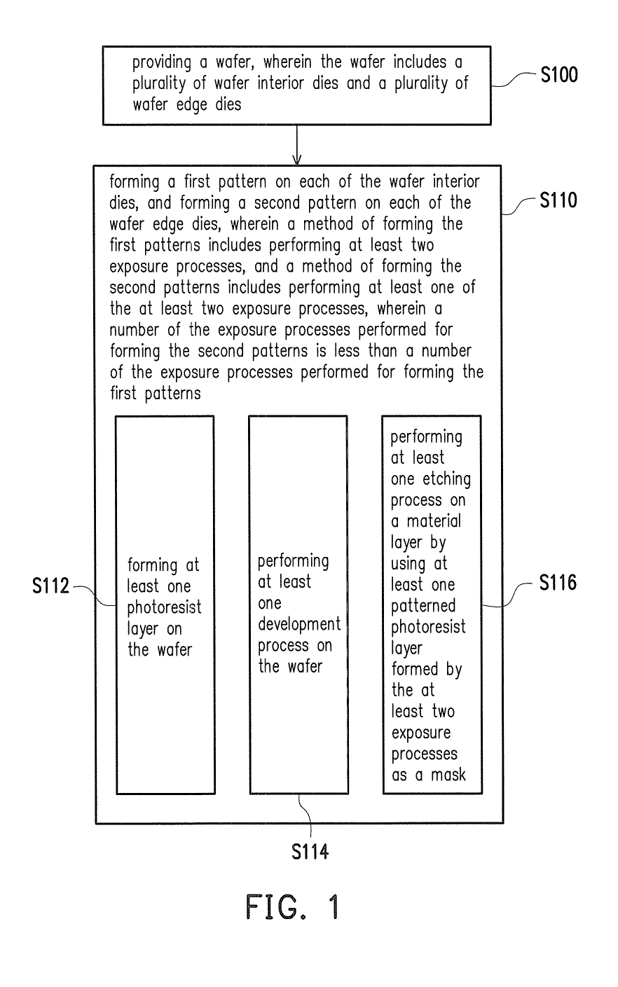

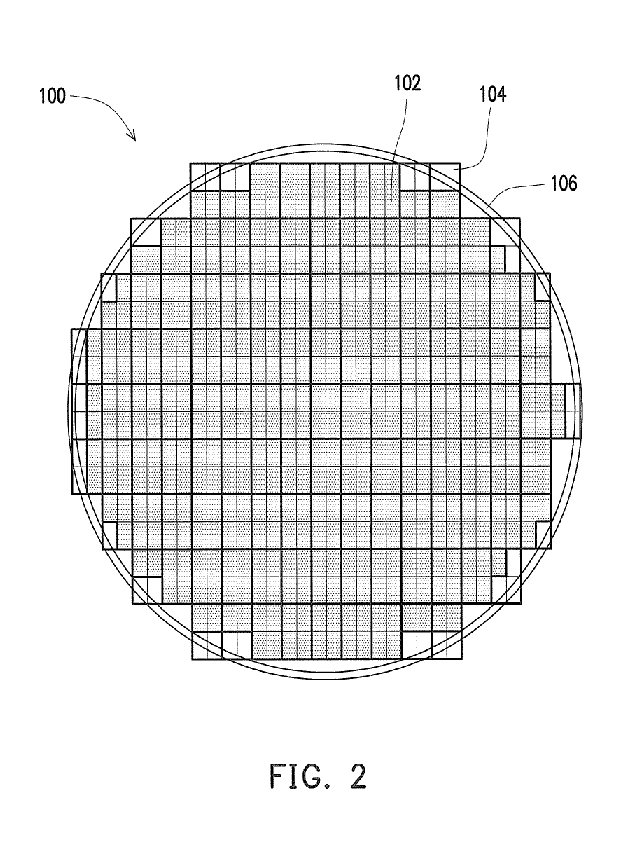

FIG. 1 is a flowchart illustrating a method of forming a pattern according to an embodiment of the invention. FIG. 2 is a schematic view illustrating a wafer according to an embodiment of the invention.

Referring to FIG. 1, a method of forming a pattern according to the present embodiment includes the following steps.

In step S100, a wafer is provided, wherein the wafer includes a plurality of wafer interior dies and a plurality of wafer edge dies.

Hereinafter, the wafer of the present embodiment is described by reference with FIG. 2. Referring to FIG. 2, a wafer 100 includes a plurality of wafer interior dies 102 and a plurality of wafer edge dies 104. The wafer interior dies 102 are dies located inside an edge contour 106 of the wafer 100, and also known as good dies in some cases. The wafer interior dies 104 are dies located on the edge contour 106 of the wafer 100, and also known as partial dies in some cases.

Referring back to FIG. 1, in step S110, a first pattern is formed on each of the wafer interior dies, and a second pattern is formed on each of the wafer edge dies. A method of forming the first patterns includes performing at least two exposure processes, and a method of forming the second patterns includes performing at least one of the at least two exposure processes, wherein a number of the exposure processes performed for forming the second patterns is less than a number of the exposure processes performed for forming the first patterns. Accordingly, the second patterns become a deformation of the first patterns. Because the number of the exposure processes performed for forming the second patterns is less than the number of the exposure processes performed for forming the first patterns, a stability of the second patterns on the wafer edge dies may be higher. Therefore, the situation in which the patterns collapse on the wafer edge dies may be effectively prevented to increase the yield rate of products. A number of the at least two exposure processes are not particularly limited, it falls in the scope of the invention for which protection is sought as long as the number of the exposure processes performed for forming the second patterns is less than the number of the exposure processes performed for forming the first patterns.

In addition, a dimension of the second patterns is, for example, greater than a dimension of the first patterns. The at least two exposure processes may be performed on different photoresist layers, or may be performed on the same photoresist layer. A method of making the number of the exposure processes performed for forming the second patterns less than the number of the exposure processes performed for forming the first patterns includes: shielding the wafer edge dies by using a mask blade when performing the at least one of the at least two exposure processes.

Step S110 may optionally include at least one of the following steps S112, S114 and S116. In step S112, at least one photoresist layer is formed on the wafer. When the at least one photoresist layer is two or more photoresist layers, these photoresist layers may be used as photoresist layers in different photolithography processes.

In step S114, at least one development process is performed on the wafer. When the at least two exposure processes are performed on the different photoresist layers, the development process may be performed on the photoresist layers respectively. When the at least two exposure processes are performed on the same photoresist layer, one development process may be performed after all the exposure processes are performed, or one development process may be performed after each time the exposure process is performed.

In an embodiment, if a target pattern of the first patterns and the second patterns is a physical pattern or an opening pattern, proceeding to step S116. The physical pattern is, for example, various semiconductor components such as a shallow trench isolation (STI) structure or a lead pattern.

In step S116, at least one etching process is performed on a material layer by using at least one patterned photoresist layer formed by the at least two exposure processes as a mask. When one patterned photoresist layer is formed by the at least two exposure processes, one etching process may be performed on the material layer to form the first patterns and the second patterns. When two or more patterned photoresist layers are formed by the at least two exposure processes, one etching process may be performed on the material layer each time the patterned photoresist layer is formed, so as to form the first patterns and the second patterns.

In another embodiment, the target pattern of the first patterns and the second patterns may also be a photoresist pattern. In this case, the at least two exposure processes are, for example, performed on the same photoresist layer. Accordingly, one development process may be performed after all the exposure processes are performed, or one development process may be performed after each time the exposure process is performed, so as to form the first patterns and the second patterns.

In view of the foregoing embodiment, it can be known that in the method of forming the pattern proposed by the invention, because the number of the exposure processes performed for forming the second patterns is less than the number of the exposure processes performed for forming the first patterns, a stability of the second patterns on the wafer edge dies may be higher. Therefore, the situation in which the patterns collapse on the wafer edge dies may be effectively prevented. Accordingly, particles formed by collapsed patterns may be prevented from falling on the location of the wafer interior dies to cause damages. As a result, the yield rate of products may be increased.

Subsequently, examples are provided below to describe the method of forming the pattern of the invention. However, the invention is not limited to the following embodiments.

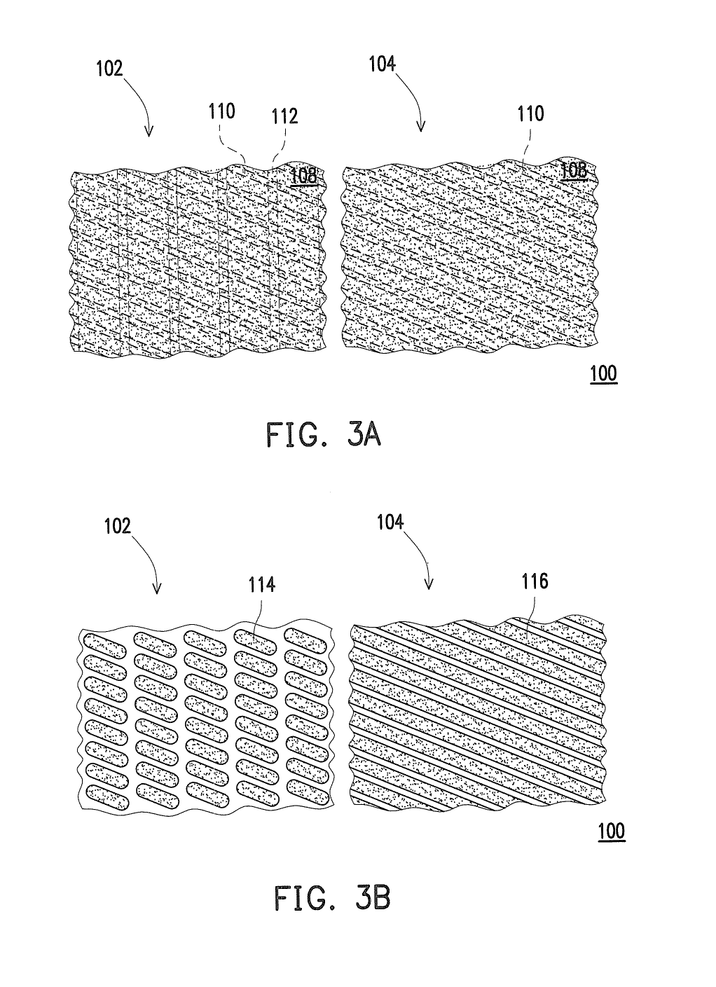

FIG. 3A to FIG. 3B are top views illustrating a process flow for the patterns according to an embodiment of the invention.

Referring to FIG. 3A, first, the wafer 100 is provided, and the wafer 100 includes the wafer interior dies 102 and the wafer edge dies 104. In FIG. 3A, one of the wafer interior dies 102 and one the wafer edge dies 104 are used as an example for clear and concise description.

A photoresist layer 108 is formed on the wafer 100. A material of the photoresist layer 108 is a positive photoresist or a negative photoresist, for example. In this embodiment, the material of the photoresist layer 108 is the positive photoresist.

The at least two exposure processes are performed on the photoresist layer 108 on the wafer interior die 102, and the at least one of the at least two exposure processes is performed on the photoresist layer 108 on the wafer edge die 104.

In this embodiment, two exposure processes are performed on the photoresist layer 108 on the wafer interior die 102. However, the invention is not limited thereto. In another embodiment, three or more exposure processes may also be performed on the photoresist layer 108 on the wafer interior die 102, and a person of ordinary skill in the art may adjust the number of the exposure processes based on demands of product design. Therein, after a first exposure process is performed, an exposed portion 110 is formed in the photoresist layer 108 on the wafer interior die 102. After a second exposure process is performed, an exposed portion 112 is formed in the photoresist layer 108 on the wafer interior die 102.

Further, during the process of performing the two exposure processes on the photoresist layer 108 on the wafer interior die 102, one of the two exposure processes is not performed on the photoresist layer 108 on the wafer edge die 104. Therein, a method of not performing the one of the exposure processes on the photoresist layer 108 on the wafer edge die 104 includes, for example, shielding the wafer edge dies 104 by using a mask blade (not illustrated). In this embodiment, the second exposure process is not performed on the photoresist layer 108 on the wafer edge die 104, and instead, only the first exposure process is performed on the photoresist layer 108 on the wafer edge die 104 to from the exposed portion 110. In another embodiment, it is also possible that the first exposure process is not performed on the photoresist layer 108 on the wafer edge die 104 while only the second exposure process is performed, as long as the number of the exposure processes performed on the photoresist layer 108 on the wafer edge die 104 is less than the number of the exposure processes performed on the photoresist layer 108 on the wafer interior die 102.

Referring to FIG. 3B, the development process is performed on the photoresist layer 108, so that patterns 114 may be formed on the wafer interior die 102, and the patterns 116 may be formed on the wafer edge die 104. A dimension (e.g., a length) of the patterns 116 is, for example, greater than a dimension of the patterns 114.

In this embodiment, although the patterns 114 and the patterns 116 are formed by the methods in the foregoing embodiment, the methods of forming the patterns 114 and the patterns 116 are not limited thereto. In another embodiment, it is also possible that one development process may be performed after each time the exposure process is performed, so as to form the patterns 114 and the patterns 116.

In view of the foregoing embodiment, it can be known that, because the number of the exposure processes performed for forming the patterns 116 is less than the number of the exposure processes performed for forming the patterns 114, a stability of the patterns 116 on the wafer edge dies 104 may be higher. Therefore, the situation in which the patterns collapse on the wafer edge dies 104 may be effectively prevented to increase the yield rate of products.

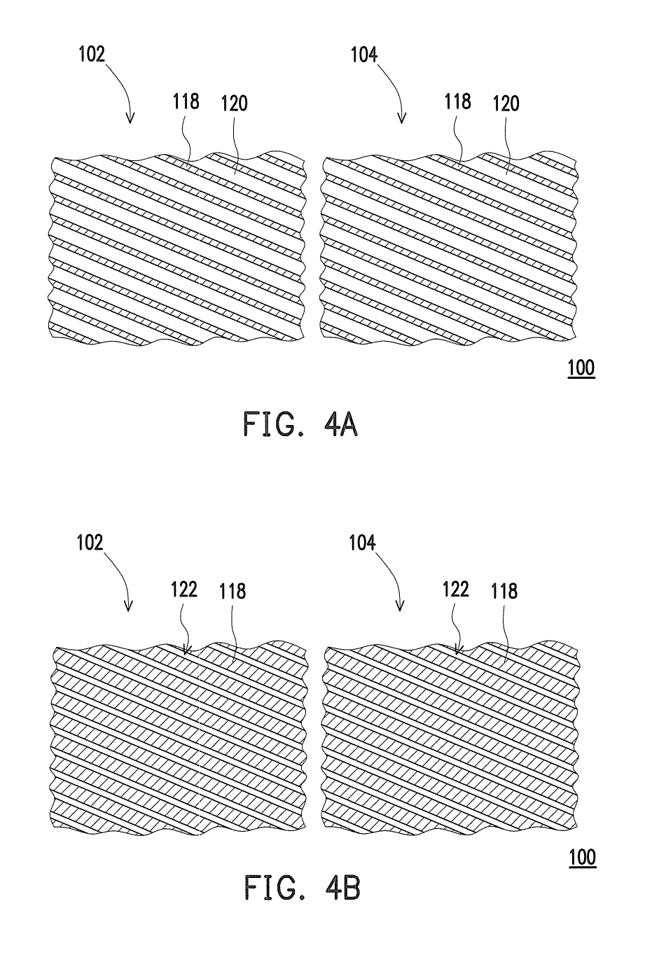

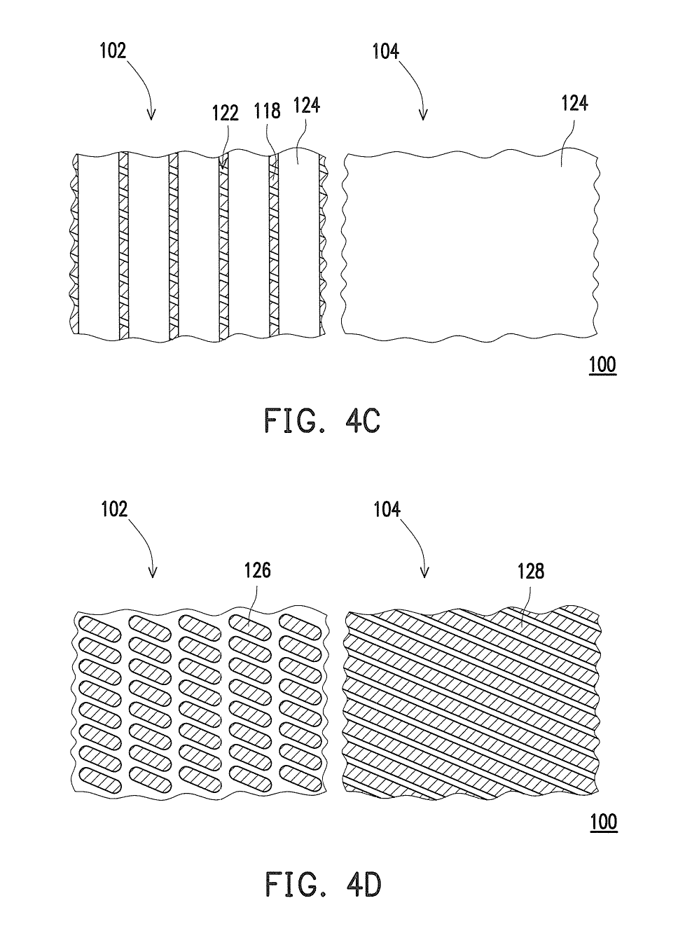

FIG. 4A to FIG. 4D are top views illustrating a process flow for the patterns according to another embodiment of the invention.

Referring to FIG. 4A, the wafer 100 is provided, and the wafer 100 includes the wafer interior dies 102 and the wafer edge dies 104. In FIG. 4A, one of the wafer interior dies 102 and one the wafer edge dies 104 are used as an example for clear and concise description.

A material layer 118 is formed on the wafer 100, and a person of ordinary skill in the art may select a material and a forming method of the material layer according to desired characteristics of components to be formed from the material layer 118.

A patterned photoresist layer 120 is formed on the material layer 118, and the patterned photoresist layer 120 exposes a part of the material 118. A method of forming the patterned photoresist layer 120 is formed by performing, for example, a photoresist-coating process, an exposure process and a development process.

Referring to FIG. 4B, the etching process is performed on the material layer 118 by using the patterned photoresist layer 120 as the mask, so as to remove the part of the material layer 118 for forming a plurality of openings 112 in the material layer 118. The etching process performed on the material layer 118 is, for example, a dry etching process.

The patterned photoresist layer 120 is removed. A method of removing the patterned photoresist layer 120 includes, for example, a dry photoresist removing method or a wet photoresist removing method.

Referring to FIG. 4C, a patterned photoresist layer 124 is formed on the material layer 118. The patterned photoresist layer 124 exposes a part of the material layer 118 on the wafer interior die 102. A material of the patterned photoresist layer 124 is a positive photoresist or a negative photoresist, for example. In the present embodiment, the material of the patterned photoresist layer 124 is the positive photoresist. A method of forming the patterned photoresist layer 124 is formed by performing, for example, a photoresist-coating process, an exposure process and a development process. Therein, during the exposure process performed for forming the patterned photoresist layer 124, the exposure process is not performed on a photoresist material on the wafer edge die 104. Therefore, the patterned photoresist layer 124 located above the wafer edge die 104 does not expose the material layer 118 on the wafer edge die 104. A method of not performing the one of the exposure processes on the photoresist material on the wafer edge die 104 includes, for example, shielding the wafer edge dies 104 by using a mask blade (not illustrated).

Referring to FIG. 4D, the etching process is performed on the material layer 118 by using the patterned photoresist layer 124 as the mask, so as to remove the part of material layer 118 on the wafer interior die 102 for enabling the material layer 118 on the wafer interior die 102 to form patterns 126 and enabling the material layer 118 on the wafer edge die 104 to form patterns 128. The etching process performed on the material layer 118 is, for example, a dry etching process. A dimension (e.g., a length) of the patterns 128 is, for example, greater than a dimension of the patterns 126.

The patterned photoresist layer 124 is removed. A method of removing the patterned photoresist layer 124 includes, for example, a dry photoresist removing method or a wet photoresist removing method.

In this embodiment, although it is illustrated by using the photolithography process in which the exposure process for forming the patterned photoresist layer 124 is not performed on the photoresist material on the wafer edge die 104, the invention is not limited thereto. In another embodiment, it is also possible that the exposure process for forming the patterned photoresist layer 120 in the photolithography process is not performed on the photoresist material on the wafer edge die 104 and only the exposure process for forming the patterned photoresist layer 124 in the photolithography process is performed on the photoresist material on the wafer edge die 104, as long as the number of the exposure processes performed for forming the patterns 128 is less than the number of the exposure processes performed for forming the patterns 126.

In this embodiment, although the patterns 126 and the patterns 128 are formed by the methods in the foregoing embodiment, the methods of forming the patterns 126 and the patterns 128 are not limited thereto. In another embodiment, it is also possible that the etching process is performed on the material layer 118 by using the patterned photoresist layers having the patterns 114 and the patterns 116 depicted in FIG. 3B as the mask, so as to form the patterns 126 and the patterns 128.

In view of the foregoing embodiment, it can be known that, because the number of the exposure processes performed for forming the patterns 128 is less than the number of the exposure processes performed for forming the patterns 126, a stability of the patterns 128 on the wafer edge dies 104 may be higher. Therefore, the situation in which the patterns collapse on the wafer edge dies 104 may be effectively prevented to increase the yield rate of products.

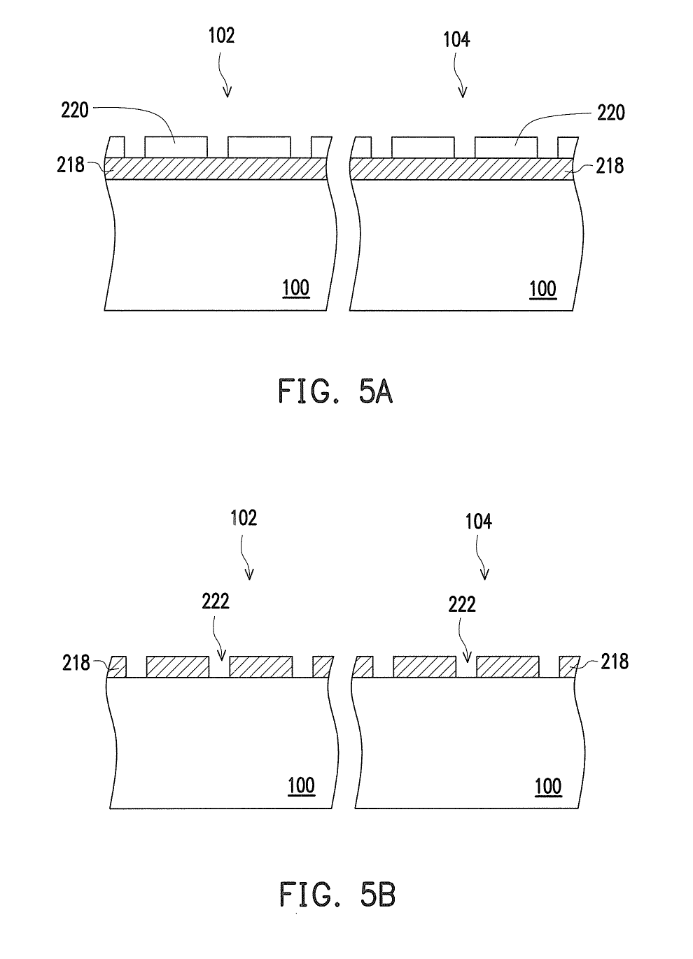

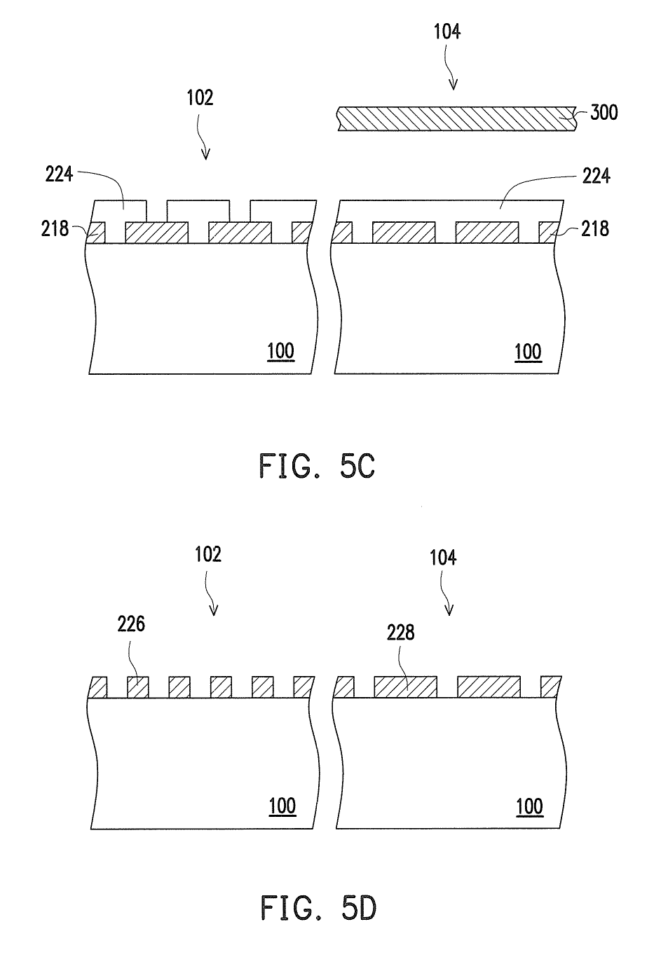

FIG. 5A to FIG. 5D are cross-sectional views illustrating a process flow for the patterns according to another embodiment of the invention.

Referring to FIG. 5A, the wafer 100 is provided, and the wafer 100 includes the wafer interior dies 102 and the wafer edge dies 104. In FIG. 5A, one of the wafer interior dies 102 and one the wafer edge dies 104 are used as an example for clear and concise description.

A material layer 218 is formed on the wafer 100, and a person of ordinary skill in the art may select a material and a forming method of the material layer according to desired characteristics of components to be formed from the material layer 218.

A patterned photoresist layer 220 is formed on the material layer 218, and the patterned photoresist layer 220 exposes a part of the material 218. A method of forming the patterned photoresist layer 220 is formed by performing, for example, a photoresist-coating process, an exposure process and a development process.

Referring to FIG. 5B, the etching process is performed on the material layer 218 by using the patterned photoresist layer 220 as the mask, so as to remove the part of the material layer 218 for forming a plurality of openings 222 in the material layer 218. The etching process performed on the material layer 218 is, for example, a dry etching process.

The patterned photoresist layer 220 is removed. A method of removing the patterned photoresist layer 220 includes, for example, a dry photoresist removing method or a wet photoresist removing method.

Referring to FIG. 5C, a patterned photoresist layer 224 is formed on the material layer 218. The patterned photoresist layer 224 exposes a part of the material layer 218 on the wafer interior die 102. A material of the patterned photoresist layer 224 is a positive photoresist or a negative photoresist, for example. In the present embodiment, the material of the patterned photoresist layer 224 is the positive photoresist. A method of forming the patterned photoresist layer 220 is formed by performing, for example, a photoresist-coating process, an exposure process and a development process. Therein, during the exposure process performed for forming the patterned photoresist layer 224, the exposure process is not performed on a photoresist material on the wafer edge die 104. Therefore, the patterned photoresist layer 224 located above the wafer edge die 104 does not expose the material layer 218 on the wafer edge die 104. A method of not performing the one of the exposure processes on the photoresist material on the wafer edge die 104 includes, for example, shielding the wafer edge dies 104 by using a mask blade 300.

Referring to FIG. 5D, the etching process is performed on the material layer 218 by using the patterned photoresist layer 224 as the mask, so as to remove the part of material layer 218 on the wafer interior die 102 for enabling the material layer 218 on the wafer interior die 102 to form patterns 226 and enabling the material layer 218 on the wafer edge die 104 to form patterns 228. The etching process performed on the material layer 218 is, for example, a dry etching process. A dimension (e.g., a width) of the patterns 228 is, for example, greater than a dimension of the patterns 226.

The patterned photoresist layer 224 is removed. A method of removing the patterned photoresist layer 224 includes, for example, a dry photoresist removing method or a wet photoresist removing method.

In this embodiment, although it is illustrated by using the photolithography process in which the exposure process for forming the patterned photoresist layer 224 is not performed on the photoresist material on the wafer edge die 104, the invention is not limited thereto. In another embodiment, it is also possible that the exposure process for forming the patterned photoresist layer 220 in the photolithography process is not performed on the photoresist material on the wafer edge die 104 and only the exposure process for forming the patterned photoresist layer 224 in the photolithography process is performed on the photoresist material on the wafer edge die 104, as long as the number of the exposure processes performed for forming the patterns 228 is less than the number of the exposure processes performed for forming the patterns 226.

In view of the foregoing embodiment, it can be known that, because the number of the exposure processes performed for forming the patterns 228 is less than the number of the exposure processes performed for forming the patterns 226, a stability of the patterns 228 on the wafer edge dies 104 may be higher. Therefore, the situation in which the patterns collapse on the wafer edge dies 104 may be effectively prevented to increase the yield rate of products.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A method of forming a pattern, comprising:
providing a wafer, wherein the wafer comprises a plurality of wafer interior dies and a plurality of wafer edge dies; and
forming a first pattern on each of the wafer interior dies, and forming a second pattern on each of the wafer edge dies, wherein
a method of forming the first patterns comprises performing at least two exposure processes, and a method of forming the second patterns comprises performing at least one of the at least two exposure processes, wherein a number of the exposure processes performed for forming the second patterns is less than a number of the exposure processes performed for forming the first patterns.

2. The method of forming the pattern of claim 1, wherein the at least two exposure processes are performed on different photoresist layers.

3. The method of forming the pattern of claim 1, wherein the at least two exposure processes are performed on the same photoresist layer.

4. The method of forming the pattern of claim 1, wherein the methods of forming the first patterns and the second patterns further comprise forming at least one photoresist layer on the wafer.

5. The method of forming the pattern of claim 1, wherein the methods of forming the first patterns and the second patterns further comprise performing at least one development process on the wafer.

6. The method of forming the pattern of claim 1, wherein the methods of forming the first patterns and the second patterns further comprise:
performing at least one etching process on a material layer by using at least one patterned photoresist layer formed by the at least two exposure processes as a mask.

7. The method of forming the pattern of claim 1, wherein the first patterns and the second patterns comprise a photoresist pattern.

8. The method of forming the pattern of claim 1, wherein the first patterns and the second patterns comprise a physical pattern or an opening pattern.

9. The method of forming the pattern of claim 1, wherein a method of making the number of the exposure processes performed for forming the second patterns less than the number of the exposure processes performed for forming the first patterns comprises:
shielding the wafer edge dies by using a mask blade when performing the at least one of the at least two exposure processes.

10. The method of forming the pattern of claim 1, wherein a dimension of the second patterns is greater than a dimension of the first patterns.
